(19) United States
(12) Patent Application Publication
(10) Pub. No.: US 2026/0164562 A1
(43) Pub. Date: Jun. 11, 2026

(54) METHOD FOR MANUFACTURING WIRING BOARD, AND WIRING BOARD

(71) Applicant: DISCO CORPORATION, Tokyo (JP)

(72) Inventor: Ken IKIGAKI, Tokyo (JP)

(21) Appl. No.: 19/385,533

(22) Filed: Nov. 11, 2025

(30) Foreign Application Priority Data
Dec. 9, 2024 (JP) 2024-215003

(51) Int. Cl. H05K 3/00; H05K 1/03

(52) U.S. Cl. CPC H05K 3/0044; H05K 1/0306; H05K 2201/09154; H05K 2203/0207; H05K 2203/0228

(57) ABSTRACT

A novel technique is provided for reducing the defect rate of a wiring board in which a laminate is formed on a core substrate. A method for manufacturing a wiring board in which a laminate is formed on a first surface side and/or a second surface side of a core substrate, the method comprising at least: forming a first processing groove having a substantially V-shaped cross-section by cutting along a division line from the first surface side by using a cutting blade; forming a second processing groove having a substantially V-shaped cross-section by cutting along the division line from the second surface side by using a cutting blade; and dividing the core substrate along the first processing groove and the second processing groove, thereby forming individual wiring boards.

### BACKGROUND

### 1. Technical Field

The present disclosure relates to a method for manufacturing a wiring board formed by disposing a laminate on a core substrate.

### 2. Description of the Related Art

Conventionally, as disclosed in, for example, JP 2015-231005 A, a wiring board (laminate) formed by laminating a core substrate (glass substrate) made of an inorganic material and an insulating layer (resin layer), which is disposed on the core substrate and in which at least one wiring layer is formed, is known as one type of printed circuit board or package substrate. This type of wiring board is used, for example, as a “core substrate for packaging” (interposer substrate) for mounting different types of semiconductor chips on both surfaces thereby connecting the chips. The wiring board is generally manufactured by dicing a material-substrate to a required size by using a known dicing apparatus (cutting apparatus) so as to singulate the same into individual pieces.

### SUMMARY

However, when a wiring board singulated by dicing to a required size using a conventional dicing method is subjected to a temperature cycling test (TCT: Temperature Cycling Test), a problem arises in that the laminate peels off from the core substrate or the laminate cracks (backside cracking), resulting in an increased defect rate of the wiring board, as a problem to be solved.

In view of the above problems, the present disclosure proposes a novel technique for reducing the defect rate of a wiring board in which a laminate is formed on a core substrate.

The problems to be solved by the present disclosure are as described above, and solutions for these problems will now be described.

According to one aspect of the present disclosure, there is provided a method for manufacturing a wiring board in which a laminate is formed on a first surface side and/or a second surface side of a core substrate, the method including at least: forming a first processing groove having a substantially V-shaped cross-section by cutting along a division line from the first surface side by using a cutting blade; forming a second processing groove having a substantially V-shaped cross-section by cutting along the division line from the second surface side by using a cutting blade; and dividing the core substrate along the first processing groove and the second processing groove, thereby forming individual wiring boards.

Further, according to one aspect of the present disclosure, in the cutting in the forming of the first processing groove and the forming of the second processing groove, at least a tip of the cutting blade is caused to reach the core substrate.

Further, according to one aspect of the present disclosure, the dividing is performed by breaking.

Further, according to one aspect of the present disclosure, the method further includes, before the forming of the first processing groove and/or the forming of the second processing groove, removing the laminate along the division line to a depth that does not reach the core substrate in a region having at least a width greater than that of the processing groove.

Further, according to one aspect of the present disclosure, there is provided a wiring board in which a laminate is formed on a first surface side and/or a second surface side of a core substrate, wherein a chamfered portion is formed so as to continuously chamfer a part of an end face of the laminate and a part of an end face of the core substrate, from a surface of the laminate formed on the first surface side and/or the second surface side to the end face of the core substrate.

Further, according to one aspect of the present disclosure, there is provided a wiring board in which a laminate is formed on a first surface side and/or a second surface side of a core substrate, wherein a chamfered portion is formed so as to continuously chamfer a part of an end face of the laminate, from a surface of the laminate formed on the first surface side and/or the second surface side to the end face of the core substrate.

The present disclosure provides the following effects.

Specifically, according to one aspect of the present disclosure, the thickness of the laminate, which has a different thermal expansion coefficient, can be reduced at an outer peripheral edge portion of the wiring board. When a temperature cycling test (TCT: Temperature Cycling Test) is performed, defects such as peeling of the laminate from the glass substrate (core substrate) or cracking (backside cracking) of the laminate at the outer peripheral edge portion can be effectively prevented, thereby reducing the defect rate of the wiring board.

### BRIEF DESCRIPTION OF THE DRAWINGS

FIG. 1A is a perspective view showing an example of a material substrate, and FIG. 1B is an enlarged cross-sectional view of a portion of the material substrate;

FIG. 2 is a flowchart showing the manufacturing method;

FIG. 3A is a diagram explaining the forming of the first processing groove, and FIG. 3B is a diagram explaining the forming of the second processing groove;

FIG. 4A is a diagram explaining the dividing, and FIG. 4B is a diagram explaining a singulated wiring board;

FIG. 5A is a diagram explaining the removing the laminate, and FIG. 5B is a diagram explaining the forming of the first processing groove;

FIG. 6A is a diagram explaining the removing the laminate, and FIG. 6B is a diagram explaining the forming of the second processing groove;

FIG. 7A is a diagram explaining the dividing, and FIG. 7B is a diagram explaining a singulated wiring board;

FIG. 8 is a diagram explaining an example of performing the removing the laminate by laser ablation processing; and

FIG. 9A is a diagram explaining a wiring board in which only the laminate is chamfered without chamfering the glass substrate at the chamfered portion, and FIG. 9B is a diagram explaining a wiring board in which only the laminate is chamfered without chamfering the glass substrate at the chamfered portion.

### DESCRIPTION OF THE PREFERRED EMBODIMENTS

Hereinafter, embodiments of the present disclosure will be described with reference to the drawings.

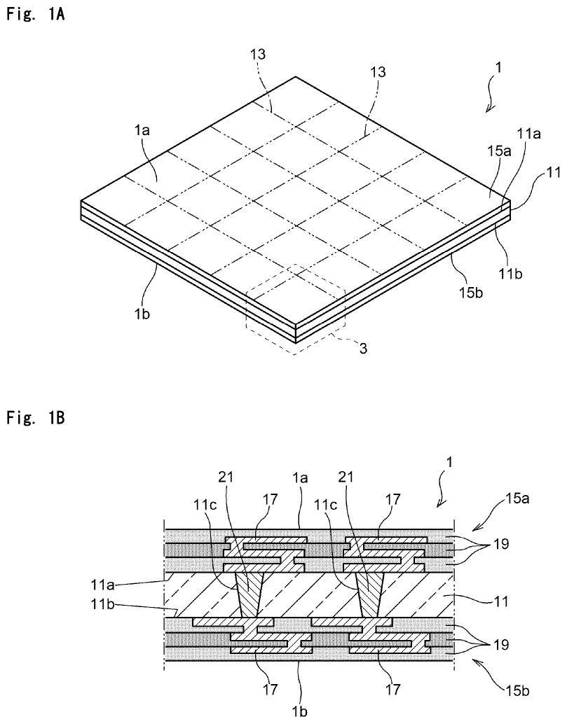

FIG. 1A is a perspective view schematically showing a configuration example of a material substrate 1 before being divided into wiring substrates, and FIG. 1B is an enlarged cross-sectional view of a portion of the material substrate 1.

As shown in FIG. 1A, the material substrate 1 is configured such that laminates 15a and 15b are formed on both surfaces of a plate-shaped glass substrate 11, and is configured as a rectangular plate-shaped substrate as a whole. The size of the material substrate 1 is, for example, 500 mm×500 mm, but the size is not particularly limited, and the material substrate 1 may be disc-shaped.

The glass substrate 11 is, for example, an alkali-free glass and functions as a so-called core substrate.

As shown in FIG. 1B, laminates 15a and 15b, each formed by laminating a plurality of layers (films), are formed on a first surface (front surface) 11a and a second surface (back surface) 11b opposite to the first surface 11a of the glass substrate 11, respectively. The laminates 15a and 15b include, for example, a wiring layer 17 made of a conductor such as metal and an insulating layer 19 made of an insulator such as resin, with the insulating layer 19 insulating between adjacent wiring layers 17.

The glass substrate 11 has a through-hole 11c formed therethrough from the first surface 11a to the second surface 11b. An electrode 21 made of a conductor such as metal is embedded in the through-hole 11c, and the wiring layer 17 on the first surface 11a side and the wiring layer 17 on the second surface 11b side are connected via the electrode 21.

In this embodiment, the material substrate 1 having laminates 15a and 15b on both the first surface 11a and the second surface 11b of the glass substrate 11 is exemplified, but the laminates 15a and 15b may be provided only on one of the first surface 11a and the second surface 11b. In such a case, the through-hole 11c and the electrode 21 can be omitted. Further, there are no particular limitations on the configuration or formation method of the laminates 15a and 15b (wiring layer 17, insulating layer 19), the through-hole 11c, the electrode 21, or the like. In addition to using the glass substrate 11 as the core substrate, a substrate made of a semiconductor such as silicon or an organic substrate formed by impregnating fibers such as glass material with a resin such as epoxy may be used as the core substrate.

As shown in FIG. 1A, by dividing the material substrate 1 configured as described above along division lines 13, a plurality of wiring boards 3 (core substrates for packaging) are manufactured. The division lines 13 (streets) are, for example, set in a grid pattern on the material substrate 1, and the material substrate is divided along the division lines 13 as described below, forming individual rectangular wiring boards 3. The size of the wiring board 3 is, for example, 50 mm×50 mm, but the size is not particularly limited.

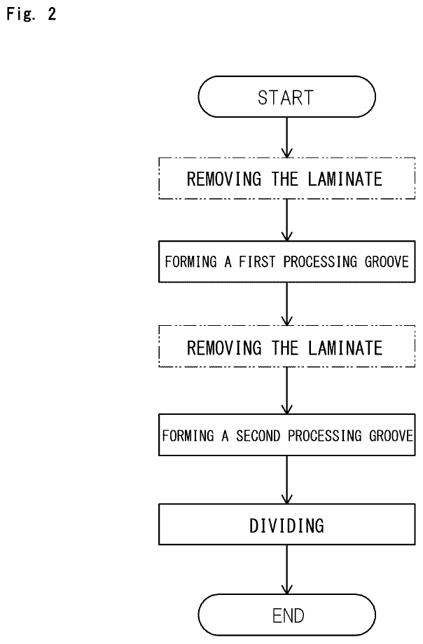

Next, a method for manufacturing the wiring board 3 by dividing the material substrate 1 shown in FIG. 1A will be described. FIG. 2 is a flowchart showing the manufacturing method.

### Forming a First Processing Groove

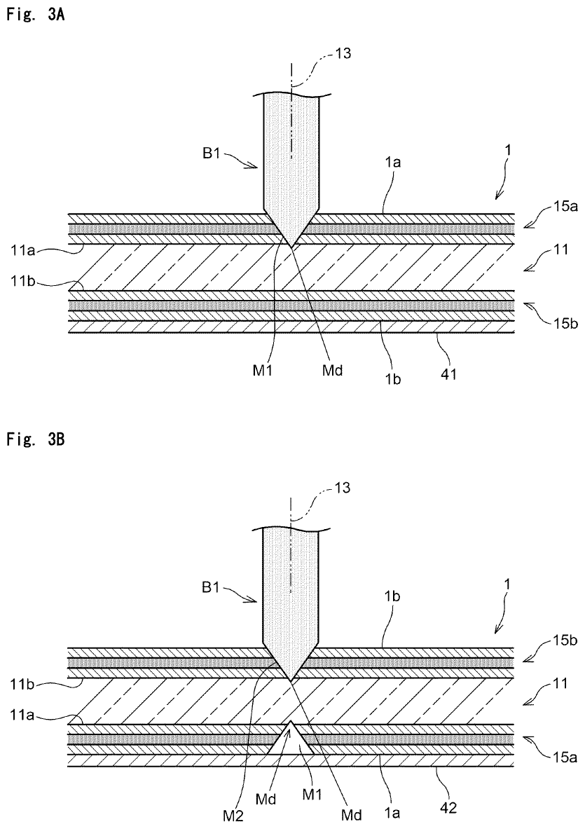

As shown in FIG. 3A, this is a step of forming a first processing groove M1 having a substantially V-shaped cross-section by cutting along the division line 13 from the first surface side using a cutting blade.

Specifically, as shown in FIG. 3A, first, the other surface 1b of the material substrate 1 is attached to a tape 41 so that one surface 1a is exposed upward, and the material substrate 1 is fixed to the tape 41. Next, a first blade B1 is used to make a cut in one laminate 15a (the laminate 15a on the first surface 11a side of the glass substrate 11) to form the first processing groove M1 in the laminate 15a.

Here, the first blade B1 is, for example, a disc-shaped cutting blade made of abrasive grains such as synthetic diamond and a binder, and is a so-called bevel blade with a substantially V-shaped tip. This allows the formation of the first processing groove M1 having a substantially V-shaped cross-section. The first blade B1 is mounted on a spindle (not shown), rotated at a predetermined speed, and makes a cut in the laminate 15a of the material substrate 1 to form the first processing groove M1.

In the cutting process of the forming of the first processing groove M1, at least the tip of the first blade B1 is caused to reach the glass substrate 11. As a result, the first processing groove M1 is formed by removing the laminate 15a and penetrating it, and further removing the surface of the first surface 11a of the glass substrate 11, such that, as shown in FIGS. 3A and 3B, the bottom Md of the first processing groove M1 is positioned inside the glass substrate 11 relative to the first surface 11a. In this manner, the cutting is carried out such that the tip of the first blade B1 makes a cut in the first surface 11a of the glass substrate 11.

In the forming of the first processing groove M1, the first processing groove M1 is formed for all division lines 13 on one surface 1a side of the material substrate 1 shown in FIG. 1A.

### Forming a Second Processing Groove

As shown in FIG. 3B, this is a step of forming a second processing groove M2 having a substantially V-shaped cross-section by cutting along the division line 13 from the second surface side using a cutting blade.

Specifically, after completing the forming of the first processing groove M1 shown in FIG. 3A, the material substrate 1 is peeled off from the tape 41, and as shown in FIG. 3B, the material substrate 1 is inverted, and one surface 1a (the surface on which the first processing groove M1 is formed) is attached to another tape 42 to fix the material substrate 1 to the tape 42. Next, similarly to FIG. 3A, as shown in FIG. 3B, the first blade B1 is used to make a cut in the other laminate 15b (the laminate 15b on the second surface 11b side of the glass substrate 11) to form the second processing groove M2 having a substantially V-shaped cross-section in the laminate 15b.

The second processing groove M2 is formed such that, similarly to the first processing groove M1 on the first surface 11a side of the glass substrate 11, the bottom Md of the second processing groove M2 is positioned inside the glass substrate 11 relative to the second surface 11b. That is, the cutting is performed so that the tip of the first blade B1 makes a cut in the second surface 11b of the glass substrate 11.

In the forming of the second processing groove M2, the second processing groove M2 is formed for all division lines 13 on the other surface 1b shown in FIG. 1A.

In the forming of the second processing groove M2, the cutting process may be performed using the same first blade B1 as in the forming of the first processing groove M1, or a different blade may be used for the cutting process.

### Dividing

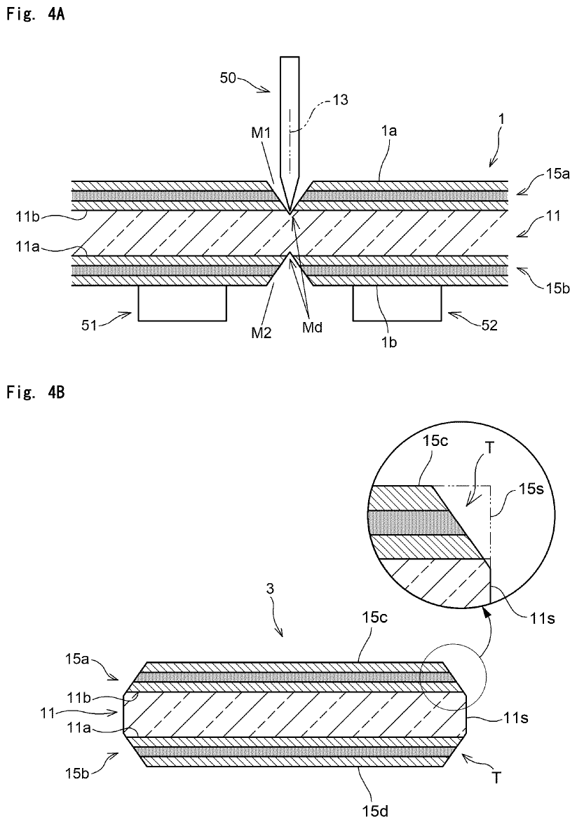

As shown in FIG. 4A, this is a step of dividing the glass substrate 11 (core substrate) along the first processing groove M1 and the second processing groove M2, thereby forming individual wiring boards.

Specifically, as shown in FIG. 4A, the glass substrate 11 is broken (cleaved) by pressing the glass substrate 11 with a pressing member 50 at the positions of the first processing groove M1 and the second processing groove M2 formed along the division lines 13.

In this embodiment, the material substrate 1 is supported from below by support members 51 and 52 so as to straddle the first processing groove M1 and the second processing groove M2 (division lines 13), and the glass substrate 11 (material substrate 1) is cleaved by pressing a pressing member 50 having a wedge-shaped tip against the first processing groove M1.

In this embodiment, since the bottoms Md of the first processing groove M1 and the second processing groove M2 are positioned inside the glass substrate 11, cleaving can be initiated from the bottoms Md. Once the cleaving has started, cracks propagate vertically in the thickness direction of the glass substrate 11, thereby improving the flatness of the end face after cleaving.

The apparatus configuration for performing breaking is not particularly limited and is not limited to the so-called three-point type using the pressing member 50 and support members 51 and 52 shown in FIG. 4A.

If breaking can be performed satisfactorily without forming the bottoms Md of the first processing groove M1 and the second processing groove M2 inside the glass substrate 11, the first processing groove M1 and the second processing groove M2 may be formed without reaching the glass substrate 11. That is, the first processing groove M1 and the second processing groove M2 may be formed only in the laminates 15a and 15b.

As described above, by forming dividing groove along the division lines 13 (FIG. 1A) in the material substrate 1, individual wiring boards 3 are formed as shown in FIG. 4B.

### Removing the Laminate

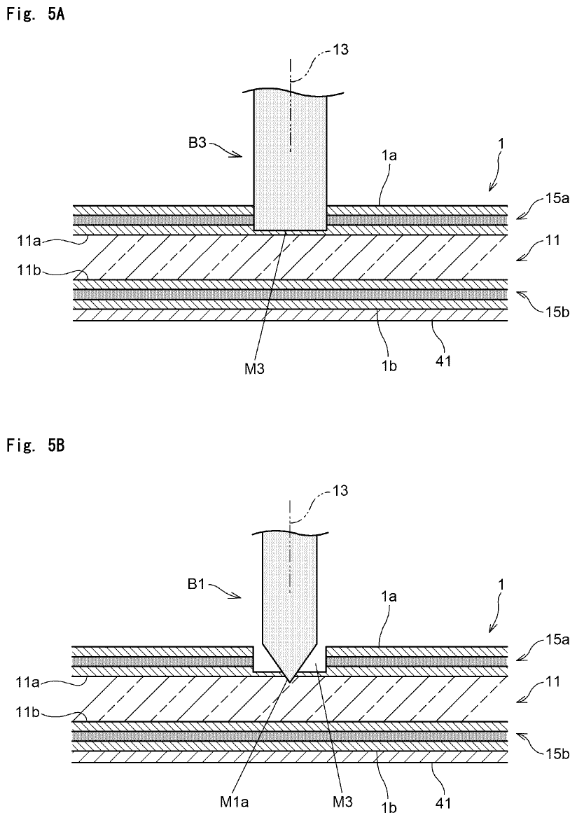

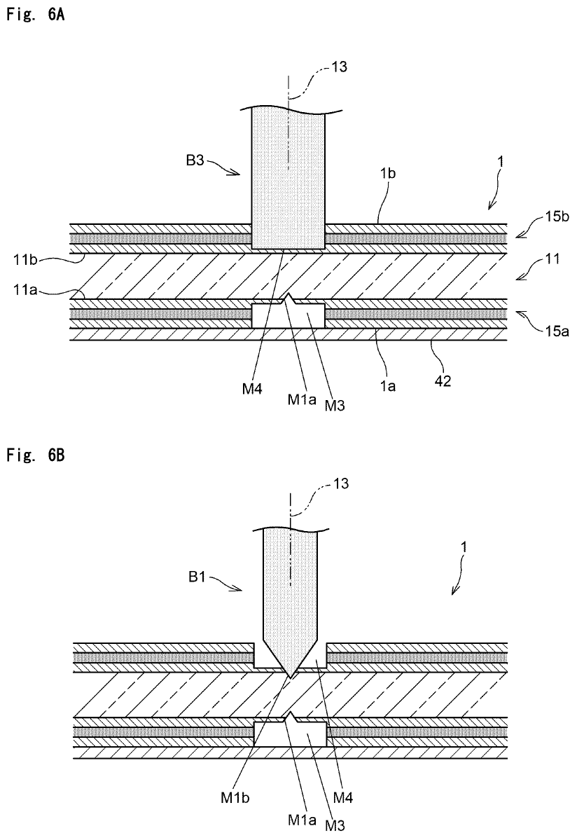

As shown in FIGS. 5A and 5B, FIGS. 6A and 6B, this is a step of removing the laminates 15a and 15b along the division lines 13 to a depth that does not reach the glass substrate 11 (core substrate) in a region having at least a width greater than that of the first processing groove M1 and the second processing groove M2 to be formed subsequently, before the forming of the first processing groove and/or the forming of the second processing groove.

This removing the laminate is optional and may be omitted.

Specifically, as shown in FIG. 5A, first, the other surface 1b of the material substrate 1 is attached to a tape 41 so that one surface 1a is exposed upward, and the material substrate 1 is fixed to the tape 41. Next, a wide third blade B3 is used to make a cut in one laminate 15a (the laminate 15a on the first surface 11a side of the glass substrate 11) of the glass substrate 11 to form a processing groove M3 in the laminate 15a.

As shown in FIG. 5B, in the state where the processing groove M3 is formed, a portion of the laminate 15a remains between the bottom of the processing groove M3 and the glass substrate 11. That is, the tip of the third blade B3 is prevented from reaching the glass substrate 11.

The width of the third blade B3 may be wider than the width of the first blade B1 (FIG. 5B), enabling the formation of a processing groove M3 wider than the first processing groove M1 (FIG. 3A).

Then, as shown in FIG. 5B, at the location of the processing groove M3, a first processing groove M1a is formed along the division line 13 using the first blade B1. In forming the first processing groove M1a, similarly to the formation of the first processing groove M1 in FIG. 3A, at least the tip of the first blade B1 is caused to reach the glass substrate 11. This allows the bottom of the first processing groove M1a formed in the glass substrate 11 to serve as a starting point for cleaving during breaking. The tip of the first blade B1 may not be caused to reach the glass substrate 11.

Next, as shown in FIG. 6A, the material substrate 1 is peeled off from the tape 41, inverted, and one surface 1a is attached to another tape 42 to fix the material substrate 1 to the tape 42. Then, the wide third blade B3 is used to make a cut in the other laminate 15b (the laminate 15b on the second surface 11b side of the glass substrate 11) to form a processing groove M4 in the laminate 15b.

Then, as shown in FIG. 6B, at the location of the processing groove M4, a second processing groove M1b is formed along the division line 13 using the first blade B1. The processing groove M4 and the second processing groove M1b shown in FIGS. 6A and 6B can be configured in the same manner as the processing groove M3 and the first processing groove M1a shown in FIGS. 5A and 5B.

Although the first processing groove M1a shown in FIG. 5B is formed after forming the processing groove M3 shown in FIG. 5A, the processing groove M4 shown in FIG. 6A may be formed after forming the processing groove M3 shown in FIG. 5A, followed by forming the first processing groove M1a shown in FIG. 5B and the second processing groove M1b shown in FIG. 6B.

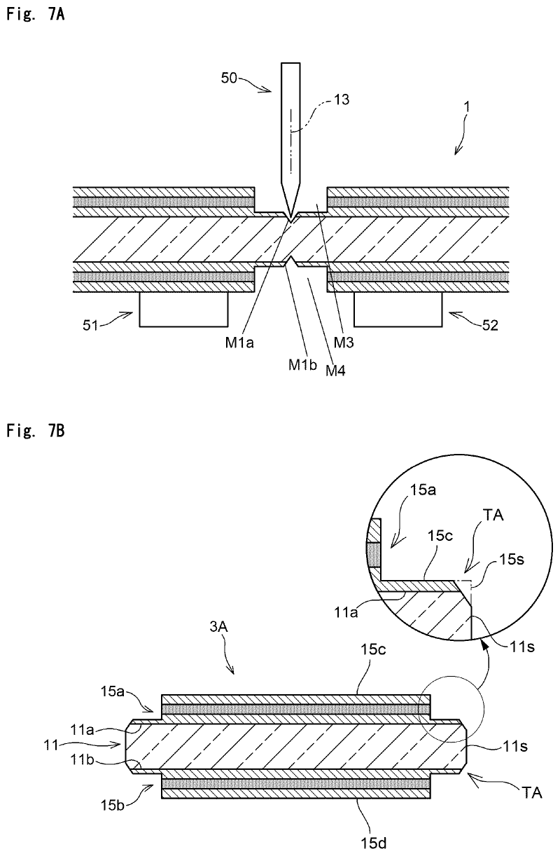

Then, as shown in FIG. 7A, for the material substrate in which the processing grooves M3 and M4, the first processing groove M1a, and the second processing groove M1b are formed as described above, breaking is performed thereby forming individual wiring boards 3A as shown in FIG. 7B.

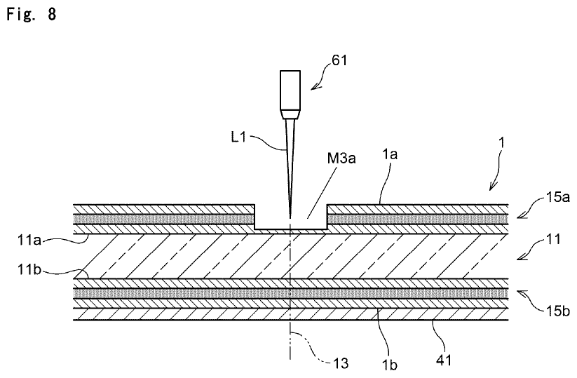

In the above embodiment, the laminate removal step is performed using the third blade B3 (FIGS. 6A and 6B), but as shown in FIG. 8, a laser beam L1 may be irradiated along the division line 13 to form a processing groove M3a wider than the first processing groove M1a to be formed later.

Specifically, as shown in FIG. 8, for the laminate 15a on the first surface 11a side, laser ablation processing is performed by irradiating a laser beam L1 from a laser beam irradiation unit 61 of a laser processing apparatus along the division line 13 to form a processing groove M3a parallel to the division line 13. The same applies to the laminate 15b on the second surface 11b side.

The present disclosure can be implemented as described above.

As shown in FIG. 4B, in the wiring board 3 manufactured according to the present disclosure, a chamfered portion T is formed, continuously chamfering an end face 15s (side surface) of the laminates 15a and 15b and a part of an end face 11s (side surface) of the core substrate, from exposed surfaces 15c and 15d of the laminates 15a and 15b formed on the first surface 11a side and/or the second surface 11b side of the core substrate (glass substrate 11) to the end face 11s of the core substrate.

Similarly, in case [symbol] when the above-described removing the laminate is performed, as shown in FIG. 7B, in the wiring board 3A, a chamfered portion TA is formed, continuously chamfering an end face 15s (side surface) of the laminates 15a and 15b and a part of an end face 11s (side surface) of the core substrate, from exposed surfaces 15c and 15d of the laminates 15a and 15b formed on the first surface 11a side and/or the second surface 11b side of the core substrate (glass substrate 11) to the end face 11s of the core substrate.

By forming the chamfered portion T (FIG. 4B) or the chamfered portion TA (FIG. 7B) as described above, the thickness of the laminates 15a and 15b, which have a different thermal expansion coefficient, can be reduced at the outer peripheral edge portion of the wiring board. When a temperature cycling test (TCT: Temperature Cycling Test) is performed, defects such as peeling of the laminates 15a and 15b from the glass substrate 11 (core substrate) or cracking (backside cracking) at the outer peripheral edge portion can be effectively prevented, thereby reducing the defect rate of the wiring board 3.

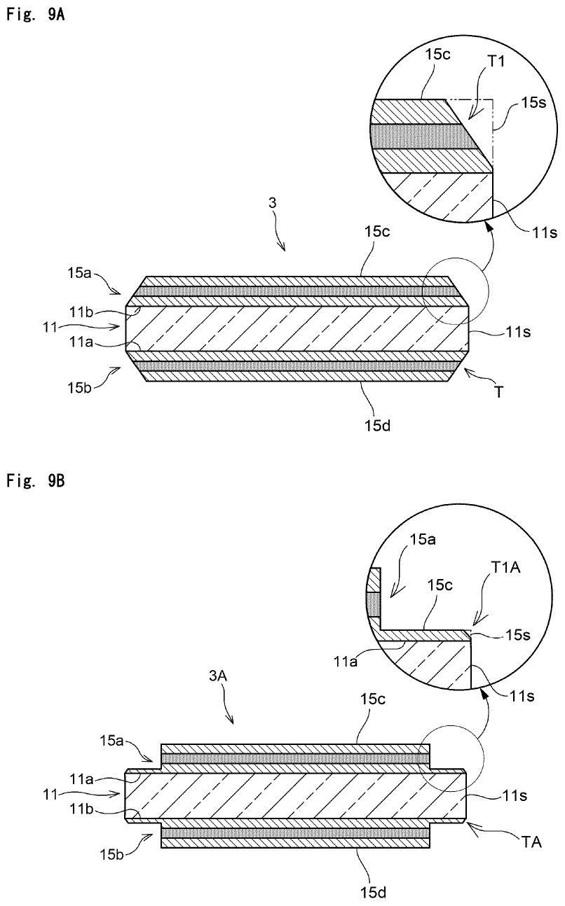

In addition to the above, as shown in FIGS. 9A and 9B, in the chamfered portions T1 and TIA, respectively, only the laminates 15a and 15b may be chamfered without chamfering the glass substrate 11. This embodiment corresponds to a case where the first processing groove M1 and the second processing groove M2 (FIGS. 3A and 3B) or the first processing groove M1a and the second processing groove M1b (FIGS. 6A and 6B) are not caused to reach the glass substrate 11.

### REFERENCE SIGNS LIST

1 Material substrate
3 Wiring board
11 Glass substrate
11a First surface
11b Second surface
11c Through-hole
11s End face
13 Division line
15a Laminate
15b Laminate
15c Exposed surface
15d Exposed surface
15s End face
17 Wiring layer
19 Insulating layer
21 Electrode
41 Tape
42 Tape
50 Pressing member
51 Support member
52 Support member
61 Laser beam irradiation unit
B1 First blade
B3 Third blade
L1 Laser beam
M1 First Processing groove
M1a First Processing groove
M1b Second Processing groove
M2 Second Processing groove
M3 Processing groove
M4 Processing groove
Md Bottom
T Chamfered portion
T1 Chamfered portion
TA Chamfered portion
T1A Chamfered portion

What is claimed is:

1. A method for manufacturing a wiring board in which a laminate is formed on a first surface side and/or a second surface side of a core substrate, the method comprising at least:
forming a first processing groove having a substantially V-shaped cross-section by cutting along a division line from the first surface side by using a cutting blade;
forming a second processing groove having a substantially V-shaped cross-section by cutting along the division line from the second surface side by using a cutting blade; and
dividing the core substrate along the first processing groove and the second processing groove, thereby forming individual wiring boards.

2. The method for manufacturing a wiring board of claim 1, wherein in the cutting in the forming of the first processing groove and the forming of the second processing groove, at least a tip of the cutting blade is caused to reach the core substrate.

3. The method for manufacturing a wiring board of claim 1, wherein the dividing is performed by breaking.

4. The method for manufacturing a wiring board of claim 2, wherein the dividing is performed by breaking.

5. The method for manufacturing a wiring board of claim 1, further comprising, before the forming of the first processing groove and/or the forming of the second processing groove, removing the laminate along the division line to a depth that does not reach the core substrate in a region having at least a width greater than that of the processing groove.

6. The method for manufacturing a wiring board of claim 2, further comprising, before the forming of the first processing groove and/or the forming of the second processing groove, removing the laminate along the division line to a depth that does not reach the core substrate in a region having at least a width greater than that of the processing groove.

7. The method for manufacturing a wiring board of claim 3, further comprising, before the forming of the first processing groove and/or the forming of the second processing groove, removing the laminate along the division line to a depth that does not reach the core substrate in a region having at least a width greater than that of the processing groove.

8. The method for manufacturing a wiring board of claim 4, further comprising, before the forming of the first processing groove and/or the forming of the second processing groove, removing the laminate along the division line to a depth that does not reach the core substrate in a region having at least a width greater than that of the processing groove.

9. A wiring board in which a laminate is formed on a first surface side and/or a second surface side of a core substrate, wherein a chamfered portion is formed so as to continuously chamfer a part of an end face of the laminate and a part of an end face of the core substrate, from a surface of the laminate formed on the first surface side and/or the second surface side to the end face of the core substrate.

10. A wiring board in which a laminate is formed on a first surface side and/or a second surface side of a core substrate, wherein a chamfered portion is formed so as to continuously chamfer a part of an end face of the laminate, from a surface of the laminate formed on the first surface side and/or the second surface side to the end face of the core substrate.
